(19) United States
(12) Patent Application Publication
(10) Pub. No.: US 2005/0045949 A1
(43) Pub. Date: Mar. 3, 2005

(54) Ultra-thin body transistor with recessed silicide contacts

(76) Inventors: Chun-Chieh Lin, Hsinchu (TW); Wen-Chin Lee, Hsin-Chu (TW); Yee-Chia Yeo, Hsin-Chu (TW); Chenming Hu, Hsin-Chu (TW)

Correspondence Address: SLATER & MATSIL, L.L.P., 17950 PRESTON ROAD, SUITE 1000, DALLAS, TX, 75252, US

(21) Appl. No.: 10/650,445

(22) Filed: Aug. 28, 2003

(51) Int. Cl. H01L 27/01

(52) U.S. Cl. 257/347; 438/479

(57) ABSTRACT

A semiconductor device (100), including a dielectric pedestal (220) located above and integral to a substrate (110) and having first sidewalls (230), a channel region (210) located above the dielectric pedestal (220) and having second sidewalls (240), and source and drain regions (410) opposing the channel region (210) and each substantially spanning one of the second sidewalls (240). An integrated circuit (800) incorporating the semiconductor device (100) is also disclosed, as well as a method of manufacturing the semiconductor device (100).

### TECHNICAL FIELD

The present invention is directed, in general, to semiconductor devices and, more specifically, to a semiconductor device having an ultra-thin body and recessed silicide contacts having sufficient thickness to avoid complete consumption during silicidation.

### BACKGROUND

It is well recognized that deep-submicron complementary metal oxide semiconductor (CMOS) transistors are the primary technology for ultra-large scale integrated (ULSI) devices. Consequently, the reduction in the size of CMOS transistors continues to be a principal focus in the quest to increase device performance and circuit density. However, as the various components of the CMOS transistors are decreased in size, their fabrication becomes more complex and operational and performance characteristics may be adversely affected.

For example, as transistors become smaller, those with shallow and ultra-shallow source and drain regions become more difficult to manufacture. In one aspect, smaller transistors may have ultra-shallow source and drain regions each having a thickness less than 30 nm. However, conventional ion implantation and diffusion-doping techniques may render such transistors susceptible to short-channel effects, which result in a dopant profile tail distribution that extends deep into the substrate. In addition, conventional ion implantation techniques have difficulty maintaining shallow source and drain regions because point defects generated in the underlying substrate during ion implantation can cause the dopant to more easily diffuse, resulting in a non-uniform doping profile and junction depth.

One attempt at overcoming the problems discussed above has been to fabricate transistors on a silicon-on-insulator (SOI) substrate. Conventional SOI-type devices include an insulative substrate attached to a thin film semiconductor substrate that contains the transistors. The insulative substrate generally includes a buried oxide (BOX) or other insulative layer above a lower semiconductor base layer. The transistors formed on such silicon-on-insulator substrates have superior performance characteristics over transistors formed on bulk substrates due, for example, to the elimination of junction capacitance, absence of reverse body effect, absence of latch-up phenomenon, and immunity to soft error phenomenon.

Transistors formed on silicon-on-insulator substrates may employ a silicon film with a thickness so small that the depletion region extends throughout the entire thickness of the silicon film. Such transistors may be known as fully depleted metal-oxide-semiconductor field-effect-transistors (MOSFETs). When the silicon film thickness is about less than a third of the gate length of the transistor, the fully-depleted MOSFET may also be known as an ultra-thin body MOSFET. The superior performance of ultra-thin body MOSFETs is also manifested in superior short-channel performance, near-ideal subthreshold voltage swing and high saturation current. Thus, as the physical gate lengths of MOSFETs shrink to dimensions of 50 nm and below, ultra-thin body MOSFETs fabricated on very thin SOI substrates provide many advantages.

However, a significant process challenge for SOI devices involves the formation of silicide layers on the source and drain regions. The source and drain regions generally have the same thickness as the semiconductor film (the silicon layer on the SOI substrate). Semiconductor films on SOI substrates can have a thickness of less than 15 nm. However, silicide layers often require a thickness of greater than 35 nm to appropriately reduce sheet resistance at the source and drain regions. Thus, conventional silicidation techniques can completely consume the source and drain regions formed in the SOI thin-film semiconductor, which can drastically increase the contact resistance and destroy the functionality of the resulting devices.

One attempt to overcome this dilemma has been to form raised source and drain regions on the semiconductor film by selective epitaxy growth (SEG). The raised source and drain regions provide additional material for contact silicidation processes while the thinner film in the channel region (active body region) controls short channel effects and reduces subthreshold slope. However, the SEG process employed to form the raised source and drain regions becomes increasingly complex as gate lengths decrease. Moreover, formation of the raised source and drain regions adds process steps to an already complex fabrication process. Furthermore, employing SEG techniques provides poor epitaxial silicon thickness uniformity, resulting in source and drain regions having unacceptable doping profiles. In addition, the SEG techniques require an activation anneal at a temperature of at least 900° C. Coupled to the disadvantage of requiring a high thermal budget is the fact that the high activation temperature can laterally diffuse the source and drain regions and cause a short under the gate structure. This problem becomes more severe as gate lengths continue to decrease.

Accordingly, what is needed in the art is a semiconductor device that overcomes the problems discussed above.

### SUMMARY OF THE INVENTION

To address the above-discussed deficiencies of the prior art, the present invention provides a semiconductor device and an integrated circuit containing the semiconductor device, wherein the semiconductor device includes: (1) a dielectric pedestal located above and integral to a substrate and having first sidewalls, (2) a channel region located above the dielectric pedestal and having second sidewalls, and (3) source and drain regions opposing the channel region and each substantially spanning one of the second sidewalls. As such, the source and drain regions may be recessed in the substrate, thereby having sufficient thickness to avoid complete consumption during a silicidation process. In addition to the increased thickness of the source and drain regions, an ultra-thin channel region may be maintained to control short channel effects and reduce subthreshold slope. Moreover, because the source and drain regions are not formed in an SOI thin-film semiconductor or by selective epitaxial growth, the uniformity of their thickness and doping profiles may be more readily controlled.

The present invention also provides a method of manufacturing a semiconductor device. The method includes providing a substrate having a channel layer located over a buried dielectric layer and forming a gate structure over the channel layer. Portions of the channel layer and the buried dielectric layer may then be removed using at least a portion of the gate structure as a mask, thereby defining a dielectric pedestal having first sidewalls and a channel region having second sidewalls. The method also includes forming source and drain regions opposing the channel region and each substantially spanning one of the second sidewalls.

The foregoing has outlined preferred and alternative features of the present invention so that those skilled in the art may better understand the detailed description of the invention that follows. Additional features of the invention will be described hereinafter that form the subject of the claims of the invention. Those skilled in the art should appreciate that they can readily use the present disclosure as a basis for designing or modifying other structures for carrying out the same purposes and/or achieving the same advantages of the present invention. Those skilled in the art should also realize that such equivalent constructions do not depart from the spirit and scope of the present disclosure.

### BRIEF DESCRIPTION OF THE DRAWINGS

The present invention is best understood from the following detailed description when read with the accompanying FIGUREs. It is emphasized that, in accordance with the standard practice in the industry, various features are not drawn to scale. In fact, the dimensions of the various features may be arbitrarily increased or reduced for clarity of discussion. Reference is now made to the following descriptions taken in conjunction with the accompanying drawings, in which:

FIG. 1 illustrates an elevation view of an embodiment of a semiconductor device in an initial stage of manufacture according to the principles of the present invention;

FIGS. 2-7 illustrate elevation views of the semiconductor device shown in FIG. 1 in subsequent stages of manufacture according to the principles of the present invention; and

FIG. 8 illustrates an elevation view of an embodiment of an integrated circuit device constructed according to the principles of the present invention.

### DETAILED DESCRIPTION OF ILLUSTRATIVE EMBODIMENTS

Referring initially to FIG. 1, illustrated is an elevation view of an embodiment of a semiconductor device 100 in an initial stage of manufacture according to the principles of the present invention. The method of manufacturing the semiconductor device 100 initiates with the provision of a substrate 110. The substrate 110 includes a bulk layer 120, a buried oxide (BOX) or other dielectric layer 130 over the bulk layer 120, and a channel layer 140 comprising silicon and/or other semiconductor materials over the dielectric layer 130. The buried oxide may comprise multiple layers including dielectric layers, such as a silicon oxide layer overlying a silicon nitride layer which overlies a silicon oxide layer, i.e., an oxide-nitride-oxide stack. The channel layer 140 may be doped via conventional processes with boron, for example, if the semiconductor device 100 is an n-channel device or phosphorous, for example, if the semiconductor device 100 is a p-channel device.

Those skilled in the art will recognize that the substrate 110 may be a silicon-on-insulator (SOI) substrate. For example, as discussed above, SOI substrates generally include a bulk layer such as the bulk layer 120, an insulator layer such as the dielectric layer 130 and a thin-film semiconductor layer such as the channel layer 140. However, in some applications the thin-film semiconductor layer of commercially available SOI substrates may not be desirable for forming a transistor channel region having particular characteristics. In such instances it may be desirable to remove the thin-film semiconductor layer from the SOI substrate and subsequently deposit, grow or otherwise form the channel layer 140 over the exposed insulator layer 130.

The dielectric layer 130 may have a thickness ranging between about 10 nm and about 5000 nm and the channel layer 140 may have a thickness ranging between about 1 nm and about 100 nm. In one embodiment, the channel layer 140 may be a thin-film semiconductor layer, which may have a thickness ranging between about 1 nm and about 20 nm. However, the present invention is not limited to layers having any particular thickness.

A gate structure 150 is formed over the substrate 110. The gate structure 150 may be substantially conventional. For example, the gate structure may include a gate oxide 160, a gate electrode 170 over the gate oxide 160, and spacers 180 on opposing sides of the gate oxide 160 and gate electrode 170. The gate oxide may have a thickness ranging between about 0.2 nm and about 2 nm, and may comprise silicon oxide, silicon oxynitride, silicon nitride, or combinations thereof. The gate oxide may also comprise a dielectric with a relative permittivity greater than about 5. Examples of such dielectrics include aluminum oxide, lanthalum oxide, hafnium oxide, and zirconium oxide. The spacers 180 may comprise multiple layers, such as an oxide lining 185 and a nitride body 187. The gate electrode may comprise a conductive material such as a metal, a metallic nitride, a metallic silicide, doped poly-crystalline silicon, or doped poly-crystalline silicon-germanium.

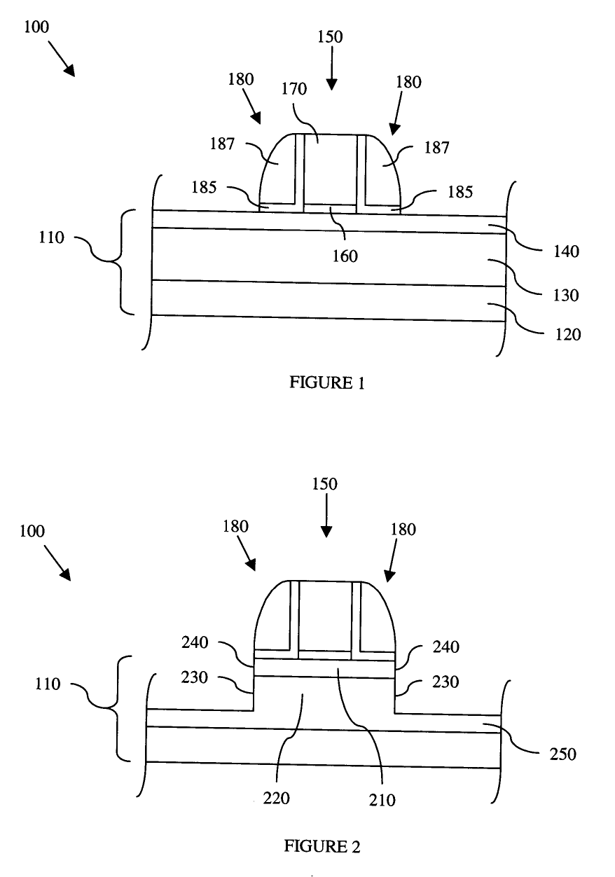

Turning to FIG. 2 with continued reference to FIG. 1, illustrated is an elevation view of the semiconductor device 100 shown in FIG. 1 after portions of the channel layer 140 and dielectric layer 130 have been removed. The portions of the channel layer 140 and dielectric layer 130 may be removed by conventional etching techniques such as dry plasma etching. Accordingly, the gate structure 150 may be employed as a mask during the etching process, thereby defining a channel region 210 and a dielectric pedestal 220 each substantially confined within the outer edges of the gate structure 150.

Although not illustrated, the formation of the channel region 210 and dielectric pedestal 220 may be performed prior to the formation of the spacers 180. In such an embodiment, the gate electrode 170 may be solely employed as an etch mask, whereby the channel region 210 and dielectric pedestal 220 may be substantially confined within the outer edges of the gate electrode 170. Such an embodiment may be advantageous in the elimination of the process steps required to form the spacers 180, although the performance characteristics of the resulting semiconductor device 100 may be altered. For the sake of simplicity, the remainder of the present disclosure will assume the inclusion of the spacers 180.

By defining the channel region 210 and dielectric pedestal as described above, the dielectric pedestal 220 includes first sidewalls 230 and the channel region 210 includes second sidewalls 240. The distance between the second sidewalls 240, or the length of the channel region 210, may range between about 2 nm and about 100 nm, although other lengths may be employed. However, in an advantageous embodiment, the length of the channel region 210 may be less than about 30 nm.

Because the channel region 210 and dielectric pedestal 220 are defined by etching that employs the same feature as an etch mask (e.g., the gate structure 150), the first sidewalls 230 and second sidewalls 240 may be substantially coincident. In general, the term “substantially” is employed herein to account for minor fluctuations in the characteristic being described. For example, by describing the first sidewalls 230 as substantially coincident with the second sidewalls 240, it is intended that the distance between the first sidewalls 230 may vary by no more than about 20% from the distance between the second sidewalls 240.

Of course, the scope of the present invention is not limited to defining the channel region 210 and dielectric pedestal 220 as having substantially coincident sidewalls 230, 240. For example, while not illustrated as such, the distance between the first sidewalls 230 of the dielectric pedestal 220 may be substantially greater than the distance between the second sidewalls 240 of the channel region 210, although such embodiments may require additional process steps.

Because the dielectric pedestal 220 is formed by removing portions of the dielectric layer 130, the dielectric pedestal 220 is integral to the substrate 110. That is, formation of the dielectric pedestal 220 may not require the deposition or other formation of additional material on the substrate 110. Moreover, as shown in FIG. 1, the dielectric pedestal 220 may be formed by only partially etching into the thickness of the dielectric layer 130, such that thinned portions 250 of the dielectric layer 130 may remain on the substrate 110 after the formation of the dielectric pedestal 220. Such partial etching of the dielectric layer 130 may be controlled by a timed etched. In another embodiment, an etch stop layer inserted into the dielectric layer 130 may be employed (not shown). The dielectric layer 130 may be an oxide-nitride-oxide stack as previously described, wherein the nitride layer acts as an etch-stop layer for the partial etching process step. Of course, the dielectric pedestal 220 may also be formed by etching completely through the thickness of the dielectric layer 130.

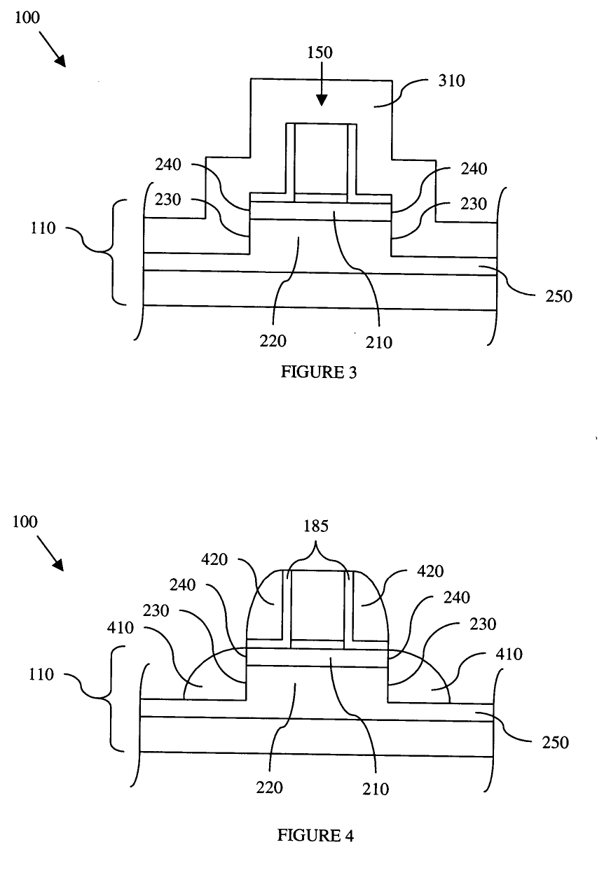

Turning to FIG. 3, illustrated is an elevation view of the semiconductor device 100 shown in FIG. 2 after the conventional removal of the nitride spacer bodies 187 (FIG. 1) and the formation of a source/drain layer 310. The source/drain layer 310 may comprise amorphous silicon, silicon-germanium, polysilicon or other material(s) suitable for forming source and drain regions. Those skilled in the art will recognize that there are myriad processes by which the source/drain layer 310 may be formed. The source/drain layer 310 may be formed by blanket deposition over the reduced dielectric layer portions 250 and the remaining gate structure 150 and spanning the first and second sidewalls 230, 240. The thickness of the source/drain layer 310 may range between about 2 nm and about 200 nm. After forming the source/drain layer 310, it may be doped via diffusion, ion implantation or other processes with, for example, boron if the semiconductor device 100 is a p-channel device or phosphorous if the semiconductor device 100 is an n-channel device. In other embodiments, source/drain layer 310 may remain un-doped until after the formation of source and drain regions, as described below.

Turning to FIG. 4, illustrated is an elevation view of the semiconductor device 100 shown in FIG. 3 after the source/drain layer 310 has been etched to form source and drain regions 410. This etch step may be accomplished by a dry plasma etching or a reactive ion etching technique. The etching process employed to form the source and drains 410 also forms sacrificial spacers 420 abutting the oxide layers 185 (FIG. 1).

The source and drain regions 410 shown in FIG. 4 each span corresponding ones of the first and second sidewalls 230, 240. However, the source and drain regions 410 need not span the first sidewalls 230 in all embodiments. For example, while not illustrated, it is conceivable that one or more features may interpose the source and drain regions 410 and the reduced dielectric layer portions 250, such that the source and drain regions 410 may not substantially span the first sidewalls 230. Similarly, the source and drain regions 410 may extend above the channel region 210, although this may increase the overall height of the semiconductor device 100. Regardless of the extent to which the source and drain regions 410 extend above and/or below the channel region 210, they should at least substantially span the second sidewalls 240 of the channel region 210. The source and drain regions 410 should also have a thickness sufficient to prevent their complete consumption during a silicidation process (described below). For example, the source and drain regions 410 may have a thickness ranging between about 2 nm and about 100 nm.

As shown in FIG. 4, the source and drain regions 410 may be recessed in the substrate 110. That is, the dielectric pedestal 220 extends integrally from the substrate 110, and the source and drain regions 410 may span the pedestal sidewalls 230. Accordingly, the source and drain regions 410 may have sufficient thickness to avoid complete consumption during a silicidation process (described below), in contrast to conventional source and drain regions formed only in an SOI thin-film semiconductor. However, despite the additional thickness of the source and drain regions 410, the channel region 210 may maintain the ultra-thin thickness necessary to control short channel effects and reduce subthreshold slope. Moreover, because the source and drain regions 410 are not formed in an SOI thin-film semiconductor or by selective epitaxial growth, the uniformity of their thickness and doping profiles may be more readily controlled. Furthermore, the source and drain regions 410 may be formed by conventional photolithography processes (e.g., deposition and patterning), thereby providing reduced complexity compared to conventional processes. In addition, the high thermal budget required for selective epitaxial growth may be avoided. For example, the deposition, doping and patterning described above to form the source and drain regions 410 may be performed at temperatures less than about 900° C.

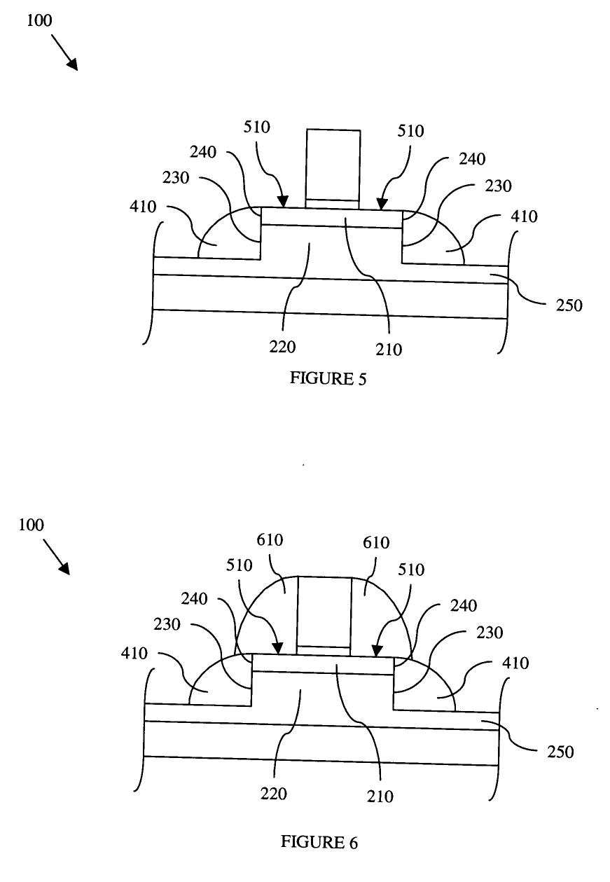

Turning to FIG. 5, illustrated is an elevation view of the semiconductor device 100 shown in FIG. 4 after the removal of the oxide layers 185 (FIG. 1) and the sacrificial spacers 420. In one embodiment, an etching process selective to the oxide layers 185 may be employed to remove the oxide layers 185 and consequently lift off the sacrificial spacers 420. The removal of the nitride layers 185 and sacrificial spacers 420 exposes surfaces 510 of the channel region 210.

Turning to FIG. 6, illustrated is an elevation view of the semiconductor device 100 shown in FIG. 5 after the formation of spacers 610 over the channel region surfaces 510. The spacers 610 also extend over portions of the source and drain regions 410, as described below. Those skilled in the art understand the many processes that may be employed to form the spacers 610, including blanket deposition of an oxide, nitride, or other suitable dielectric, and subsequent anisotropic etching.

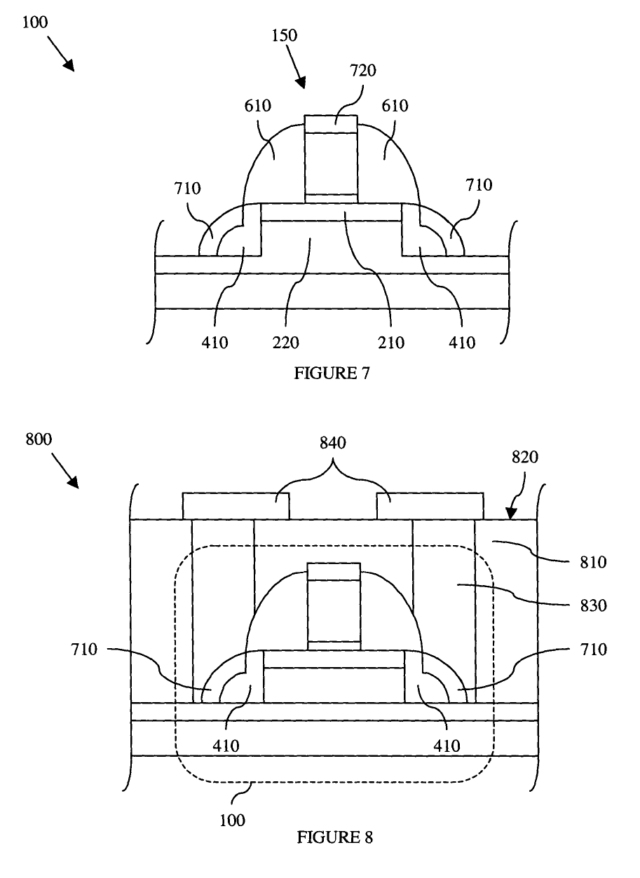

Turning to FIG. 7, illustrated is an elevation view of the semiconductor device 100 shown in FIG. 6 after the formation of silicide layers 710 over portions of the source and drain regions 410. A silicide layer 720 may also be formed over the gate structure 150 concurrent with the formation of the silicide layers 710. However, in addition to extending above the source and drain regions 410 and gate structure 150, the formation of the silicide layers 710, 720 may partially consume the source and drain regions 410 and gate structure 150. Accordingly, the description of the silicide layers 710, 720 as being formed “over” the source and drain regions 410 and gate structure 150 is intended to also include those portions of the silicide layers 710, 720 that consume portions of the source and drain regions 410 and gate structure 720.

The silicide layers 710, 720 may be formed by conventional silicidation processes. However, the portions of the silicide layer 710 formed over the source and drain regions 410 are formed by employing the spacers 610 as masks. Because the spacers 610 extend over portions of the source and drain regions 410, the silicide layers 710 are isolated from the channel region 210 by portions of the source and drain regions 410. This separation between the silicide layers 710 and the channel region 210 prevents shorting the silicide layers 710 and the channel region 210. However, the extent to which the silicide layers 710 are separated from the channel region 210, and the extent to which the spacers 610 overlap the source and drain regions 410, may be determined on an application-specific basis.

The formation of the silicide layers 710, 720 lowers the contact resistance of the source and drain regions 410 and gate structure 150. For example, the contact resistivity of the source and drain regions 410 may be less than about 0⁻⁸ Ω cm². Moreover, as discussed above, most conventional silicidation processes consume portions of the source and drain regions. However, as also discussed above, the source and drain regions 410 of the present invention have sufficient thickness to prevent their complete consumption during the silicidation process.

Turning briefly to FIG. 8 with continued reference to FIGS. 1-7, illustrated is an elevation view of an embodiment of an integrated circuit 800 constructed according to the principles of the present invention. The integrated circuit 800 may be one environment in which the semiconductor device 100 shown in FIGS. 1-7 may be implemented. Accordingly, the reference numbers shown in FIGS. 1-7 have been carried into FIG. 8 where possible.

The integrated circuit 800 includes an interlevel dielectric layer 810 conventionally formed over the semiconductor device and subsequently planarized, such as by chemical-mechanical polishing, thereby including a substantially planar surface 820. Conductive vias 830 extend through the interlevel dielectric layer 810 from its surface 820 and electrically contact at least portions of the silicide layers 710 of the source and drain regions 410. Conductive interconnects 840 are also formed over the interlevel dielectric surface 820 and electrically contact the conductive vias 830. Those skilled in the art will recognize that the integrated circuit 800 may include additional features not illustrated or described herein, such as additional semiconductor devices, vias and interconnects.

Although the present invention has been described in detail, those skilled in the art should understand that they can make various changes, substitutions and alterations herein without departing from the spirit and scope of the invention.

1. A semiconductor device, comprising:
a layer of dielectric material overlying a substrate:
a dielectric pedestal disposed within and integral to said layer of dielectric material located above remaining portions of said layer of dielectric material and having first sidewalls;
a semiconductor channel region located above said dielectric pedestal and having second sidewalls; and
source and drain semiconductor regions disposed adjacent said first sidewalls of said dielectric pedestal and partially overlying said remaining portions of the layer of dielectric material opposing said channel region and each substantially spanning one of said second sidewalls.

2. The semiconductor device as recited in claim 1 wherein said first and second sidewalls are substantially coincident.

3. The semiconductor device as recited in claim 1 wherein each of said source and drain regions further substantially spans one of said first sidewalls.

4. The semiconductor device as recited in claim 1 wherein said dielectric pedestal and said substrate comprise at least a portion of a silicon-on-insulator (SOI) substrate.

5. The semiconductor device as recited in claim 1 wherein said channel region, said dielectric pedestal and said substrate comprise at least a portion of a silicon-on-insulator (SOI) substrate.

6. The semiconductor device as recited in claim 1 wherein said dielectric pedestal is at least a portion of a buried oxide (BOX) layer located in said substrate.

7. The semi conductor device as recited in claim 1 further comprising a silicide layer over at least portions of said source and drain regions.

8. The semiconductor device as recited in claim 1 further comprising a gate structure including a gate oxide located above said channel region and a gate electrode located above said gate oxide.

9. The semiconductor device as recited in claim 8 wherein said gate oxide has a thickness ranging between about 0.2 nm and about 2 nm.

10. The semiconductor device as recited in claim 1 wherein said channel region has a length ranging between about 2 nm and about 100 nm.

11. The semiconductor device as recited in claim 1 wherein said channel region has a thickness ranging between about 1 nm and about 20 nm.

12-25. (Canceled)

26. An integrated circuit device, comprising:
a semiconductor device, including:
a layer of dielectric material formed over a substrate:
a dielectric pedestal within and integral to said layer of dielectric material and located above remaining portions of said layer of dielectric material and having first sidewalls;
a channel region located above said dielectric pedestal and having second sidewalls; and
source and drain semiconductor regions disposed adjacent the first sidewalls of said dielectric pedestal and disposed partially overlying said remaining portions of said dielectric layer and opposing said channel region and each substantially spanning one of said second sidewalls;
an interlevel dielectric layer located over said semiconductor device; and
vias spanning said interlevel dielectric layer and contacting said source and drain regions.

27. The integrated circuit device as recited in claim 26 wherein said first and second sidewalls are substantially coincident.

28. The integrated circuit device as recited in claim 26 wherein each of said source and drain regions further substantially spans one of said first sidewalls.

29. The integrated circuit device as recited in claim 26 wherein said dielectric pedestal and said substrate form at least a portion of a silicon-on-insulator (SOI) substrate.

30. The integrated circuit device as recited in claim 26 wherein said channel region, said dielectric pedestal and said substrate form at least a portion of a silicon-on-insulator (SOI) substrate.

31. The integrated circuit device as recited in claim 26 wherein said dielectric pedestal is at least a portion of a buried oxide (BOX) layer located in said substrate.

32. The integrated circuit device as recited in claim 26 wherein said semiconductor device includes a silicide layer over at least portions of said source and drain regions.

33. The integrated circuit device as recited in claim 26 wherein said semiconductor device includes a gate structure having a gate oxide located above said channel region and a gate electrode located above said gate oxide.

34. The integrated circuit device as recited in claim 33 wherein said gate oxide has a thickness ranging between about 0.2 nm and about 2 nm.

35. The integrated circuit device as recited in claim 26 wherein said channel region has a length ranging between about 2=n and about 100 nm.

36. The integrated circuit device as recited in claim 26 wherein said channel region has a thickness ranging between about 1 nm and about 20 nm.
